(19) United States
(12) Patent Application Publication
(10) Pub. No.: US 2017/0159178 A1
(43) Pub. Date: Jun. 8, 2017

(54) ALD/PARYLENE MULTI-LAYER THIN FILM STACK

(71) Applicant: HZO, Inc., Draper, UT (US)

(72) Inventors: Layton Baker, Draper, UT (US); Yang Yun, Draper, UT (US); Chien-Lan Hsueh, Draper, UT (US)

(73) Assignee: HZO, Inc., Draper, UT (US)

(21) Appl. No.: 15/361,293

(22) Filed: Nov. 25, 2016

Related U.S. Application Data
(60) Provisional application No. 62/259,353, filed on Nov. 24, 2015.

(51) Int. Cl. C23C 16/455; C23C 16/40

(52) U.S. Cl. CPC C23C 16/45529; C23C 16/403; C23C 16/405; C23C 16/402; C23C 16/45555

(57) ABSTRACT

Described herein is a multi-layer thin film stack including a first ALD layer of a first metal oxide deposited on a substrate surface of a substrate, a first parylene layer covering the first ALD layer, and a second ALD layer of a second metal oxide covering the first parylene layer. The multi-layer thin film stack further includes a second parylene layer covering the second ALD layer.

### CROSS-REFERENCES TO RELATED APPLICATION

This application claims the benefit of U.S. Provisional Patent Application No. 62/259,353 entitled “ALD/PARYLENE MULTI-LAYER THIN FILM STACK” and filed on Nov. 24, 2015 for Layton Baker et al., which is incorporated herein by reference.

### TECHNICAL FIELD

This disclosure relates generally to coatings and methods of preparing components within an electronic device with coatings of alternating layers of metal oxide and parylene. More specifically, the disclosed subject matter relates to coatings and methods of forming coatings by utilizing low temperature atomic layer deposition (ALD) to deposit layers of metal oxide and also depositing parylene layers alternating between the metal oxide layers.

### BACKGROUND

The durability of electronic devices in harsh environmental conditions is of major interest in industrial and consumer electronics. In electronic applications, electronic assemblies are frequently exposed to corrosive environments (e.g., high temperatures, water, steam, acids, organic solvents, salt, etc. and combinations thereof) which can cause rapid failure of electronic components and circuits on the electronics assembly. In consumer electronics, the most common corrosive environmental exposures are accidental water spray or immersion. Electronics are commonly housed within a protective case or enclosure which is designed, in part, to limit exposure of the electronics assembly and components to water and other corrosive solids, liquids, and gases. The protective cases/enclosures typically do not provide complete protection and add volume and mass to electronic products.

An alternative to corrosion-resistant cases arises from encapsulating the underlying electrical components within device enclosures. For example, a thin film or protective coating can be applied to the electronic circuitry and/or components inside of an electronic device. This protective coating fully encapsulates and protects the electronic device from corrosive chemical species, such as water, without requiring a bulky external protective case. Such corrosion-resistant coatings are desirable for protection against incidental or accidental exposure to water and other corrosive species. For instance, a thin film coating may protect the electronic components of a consumer electronics device from corrosion, and eventual failure, due to high humidity, rain, spilled drinks, immersion or even full submersion in water.

There remains, therefore, a need in the art to provide alternative coatings that might be applied to the circuitry and components of an electronic device that offer extended protection from corrosive chemical species exposure, as well resistance to mechanical handling and wear and that might impart additional desirable properties such as electromagnetic resistance, oxidation resistance, or desirable optical properties.

### SUMMARY

The subject matter of the present application has been developed in response to the present state of the art, and in particular, in response to the shortcomings of electronic device and substrate coatings, that have not yet been fully solved by currently available techniques. Accordingly, the subject matter of the present application has been developed to provide a stack of alternating layers of metal oxide and parylene to overcome at least some of the above-discussed shortcomings of prior art techniques.

According to one embodiment, a multi-layer thin film stack including a first ALD layer of a first metal oxide deposited on a substrate surface of a substrate, a first parylene layer covering the first ALD layer, and a second ALD layer of a second metal oxide covering the first parylene layer. The multi-layer thin film stack further includes a second parylene layer covering the second ALD layer. In some implementations, there are multiple alternating layers of ALD layers and parylene layers.

According to some implementations of the multi-layer thin film stack, the first ALD layer includes an alloy of two or more following metal oxide materials: aluminum oxide (Al₂O₃), titanium dioxide (TiO₂), silicon dioxide (SiO₂), and zirconium oxide (ZrO₂).

In some implementations, the second ALD layer includes an alloy of two or more following metal oxide materials: aluminum oxide (Al₂O₃), titanium dioxide (TiO₂), silicon dioxide (SiO₂), and zirconium oxide (ZrO₂).

In some embodiments, the first and second ALD layer are the same alloy. In some embodiments, the first and second ALD layer are a different alloy

In certain implementations of the multi-layer thin film stack, the parylene is selected from parylene A, parylene C, parylene N, parylene D, parylene VT-4, parylene AF-4, as well as mixtures and/or derivations of the same. In some embodiments, the polymer is selected from parylene C and parylene N.

In some embodiments, the first parylene layer and the second parylene layer are a same parylene material. In some embodiments, the first parylene layer and the second parylene layer are a different parylene material.

In some embodiments, the first and second ALD layers each have a thickness between 10 and 30 nm. In some embodiments, the first and second ALD layers each have a thickness between 5 and 50 nm. In some embodiments, the first parylene layer has a thickness between 300 nm and 1000 nm.

In some embodiments, the thin film stack further includes a third ALD layer of a third metal oxide covering the second parylene layer, a third parylene layer covering the third ALD layer, a fourth ALD layer of a fourth metal oxide covering the third parylene layer, and a fourth parylene layer covering the fourth ALD layer.

According to one embodiment, a process for forming a multi-layer thin film stack on a substrate is disclosed. The method includes depositing a first ALD layer of a first metal oxide to a substrate surface of a substrate, depositing a first parylene layer onto a surface of the first ALD layer to cover the first ALD layer, depositing a second ALD layer of a second metal oxide onto a surface of the first parylene layer, and depositing a second parylene layer onto a surface of the second ALD layer to cover the second ALD layer.

In some embodiments, the parylene is selected from parylene A, parylene C, parylene N, parylene D, parylene VT-4, parylene AF-4, as well as mixtures and derivatives of the same.

In some embodiments, the first ALD layer is an alloy of two or more following metal oxide materials: aluminum oxide (Al₂O₃), titanium dioxide (TiO₂), silicon dioxide (SiO₂), and zirconium oxide (ZrO₂).

In some embodiments, the process further includes depositing a third ALD layer of a third metal oxide onto a surface of the second parylene layer, and depositing a third parylene layer onto a surface of the third ALD layer to cover the third ALD layer.

In some implementations, the first or second ALD layer is deposited at a temperature between 60-100° C.

In one aspect, a coated article prepared from the processes disclosed herein is also disclosed.

The described features, structures, advantages, and/or characteristics of the subject matter of the present disclosure may be combined in any suitable manner in one or more embodiments and/or implementations. In the following description, numerous specific details are provided to impart a thorough understanding of embodiments of the subject matter of the present disclosure. One skilled in the relevant art will recognize that the subject matter of the present disclosure may be practiced without one or more of the specific features, details, components, materials, and/or methods of a particular embodiment or implementation. In other instances, additional features and advantages may be recognized in certain embodiments and/or implementations that may not be present in all embodiments or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the present subject matter will be readily understood, a description of the present subject matter will be rendered by reference to specific embodiments that are illustrated in the appended drawings. Understanding that these drawings depict only typical embodiments of the present subject matter and are not therefore to be considered to be limiting of its scope, the present subject matter will be described and explained with detail through the use of the accompanying drawings, in which:

FIG. 1 is a cross-sectional view of a substrate with a metal oxide layer deposited on a substrate, according to one or more embodiments of the present disclosure;

FIG. 2 is a cross-sectional view of a substrate with alternating layers of metal oxide and parylene deposited on a substrate, according to one or more embodiments of the present disclosure; and

FIG. 3 is a schematic diagram of a process for depositing a composite coating on a substrate, according to one or more embodiments of the present disclosure.

### DETAILED DESCRIPTION

Reference throughout this specification to “one embodiment,” “an embodiment,” or similar language means that a particular feature, structure, or characteristic described in connection with the embodiment is included in at least one embodiment of the present disclosure. Appearances of the phrases “in one embodiment,” “in an embodiment,” and similar language throughout this specification may, but do not necessarily, all refer to the same embodiment. Similarly, the use of the term “implementation” means an implementation having a particular feature, structure, or characteristic described in connection with one or more embodiments of the present disclosure, however, absent an express correlation to indicate otherwise, an implementation may be associated with one or more embodiments.

In order that the advantages of the subject matter may be more readily understood, a more particular description of the subject matter briefly described above will be rendered by reference to specific embodiments that are illustrated in the appended drawings. Understanding that these drawings depict only typical embodiments of the subject matter and are not therefore to be considered to be limiting of its scope, the subject matter will be described and explained with additional specificity and detail through the use of the drawings.

The term “corrosion resistant” refers to the ability of a coating to prevent exposure of a coated element or feature to corrosive chemical species. With the context of an electronic device, corrosive chemical species include any chemical, gas, liquid, or solid, which causes or facilitates degradation of materials on the electronic device. Examples of such corrosive chemical species include, but are not limited to, (a) humid warm air, (b) liquid water, (c) salts such as from seas and oceans (e.g., salt water immersion; humid, salty air in coastal environments), (d) organic vapors and liquids such as diesel fuel, jet fuel, gasoline, acetone, alcohols, and mixtures thereof, (e) acids such as aqueous hydrochloric acid or hydrochloric acid vapor, (f) bases such as aqueous ammonia or ammonia vapor, and (g) gaseous corrosive species such as sulfur dioxide and sulfur trioxide, which may adsorb on the surface of electronic components. A corrosion resistant coating may resist wetting or penetration by one or more types of corrosive chemical species, or it may be impermeable or substantially impermeable to one or more types of corrosive chemical species. A corrosion resistant coating may repel one or more types of corrosive chemical species such as salt solutions, acidic solutions, basic solutions, drinks, etc. or vapors of water or other aqueous materials (e.g., humidity, fogs, mists, etc.), wetness, etc. Use of the term “corrosion resistant” to modify the term “coating” should not be considered to limit the scope of materials from which the coating protects one or more components of an electronic device. The term “corrosion resistant” may also refer to the ability of a coating to restrict permeation of or repel organic liquids or vapors (e.g., organic solvents, other organic materials in liquid or vapor form, etc.), as well as a variety of other substances or conditions that might pose a threat to a substrate, such as an electronic device or its components.

As used herein, the terms “stack” and “thin film stack” refer to a combination of layers of metal oxide and parylene material. In some embodiments, a stack may include a near surface region of the parylene material where metal oxide is also present in the parylene material, having diffused into the near surface region as a metal oxide precursor which subsequently oxidizes into a metal oxide. The resulting near surface region of the parylene material may be a hybrid material made up of parylene polymer and metal oxide. It is also understood that the term ‘coating’ and ‘thin film stack’ may be used interchangeably.

Multi-layer thin film stack systems, or, more simply, stacks, for imparting substrates with resistance are disclosed. Such a stack may be used on any suitable substrate, including, without limitation, components that will reside within the interior of an electronic device.

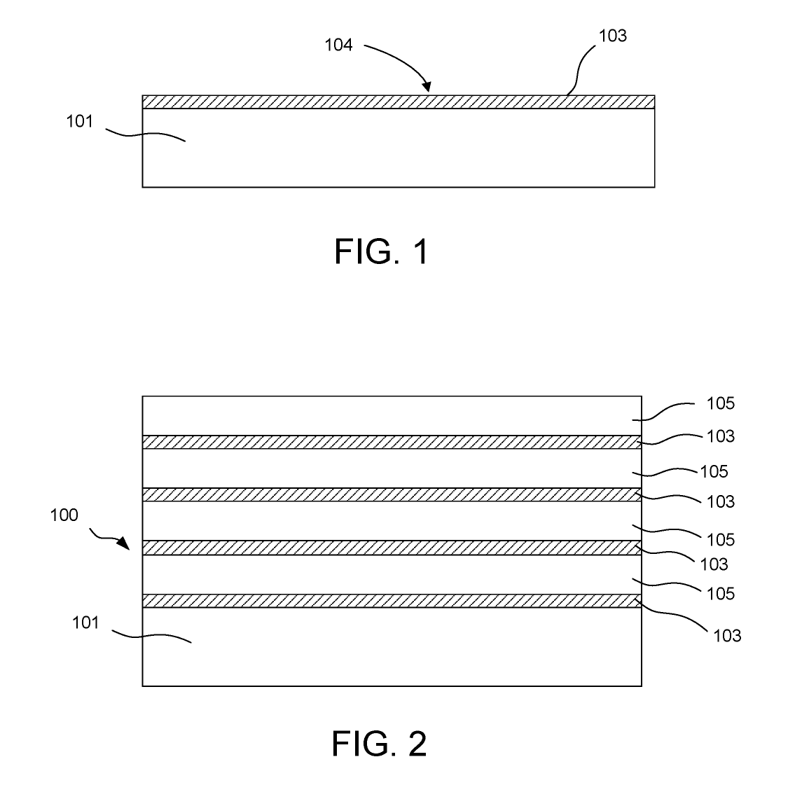

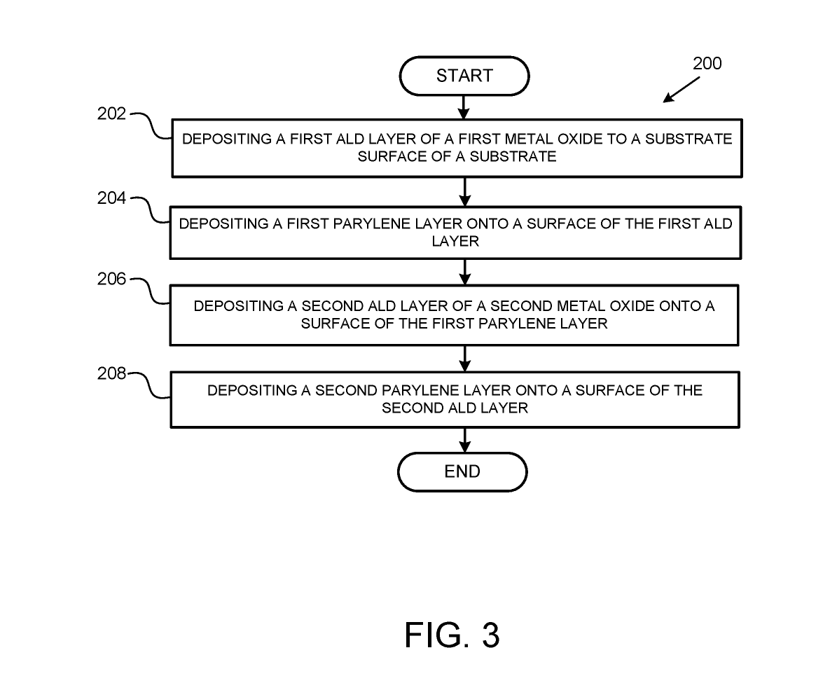

A series of alternating layers, made up of metal oxide layers and parylene layers is described herein. Referring to FIG. 1, a cross-sectional view of a substrate 101 with a metal oxide layer 103 is shown. The metal oxide layer 103 includes an outer surface 104 onto which a parylene layer may be deposited which is described in more detail in conjunction with FIGS. 2 and 3.

Referring to FIG. 2, a representative embodiment of a thin film stack 100 is shown. Each metal oxide layer may be derived from an atomic layer deposition (ALD) process. In some embodiments, metal oxide layers are deposited using low temperature ALD processes.

In the illustrated embodiment, the thin film stack 100 includes a superlattice of metal oxide and parylene with four periods, or dyads. Other embodiments may have fewer or more periods, or dyads. For example, some embodiments may have any number up to as many as ten or twenty dyads or as few as two.

FIG. 2 provides a graphical depiction of one embodiment of the multi-layer thin film stack 100. In a specific implementation, each metal oxide layer 103 is ten to thirty nanometers thick and is comprised of an alloy or nanolaminate of two or more following metal oxide materials: aluminum oxide (Al₂O₃), titanium dioxide (TiO₂), silicon dioxide (SiO₂), and/or zirconium oxide (ZrO₂). In other embodiments, the metal oxide layer may be a different thickness. For example, the metal oxide layer 103 may be as thin as one nanometer, two nanometers, or five nanometers. In another example, the metal oxide layer may be as thick as fifty nanometers, eighty nanometers, or one hundred nanometers. Additionally, other embodiments may use other metal oxide materials which are similar or equivalent to the metal oxide materials listed above. In some embodiments, the thickness of each metal oxide layer 103 may vary in a plurality of dyads. For example, the thickness of each metal oxide layer 103 may increase is each succeeding dyad or decrease in each succeeding dyad.

As shown in FIG. 2, a substrate 101 is covered by a first metal oxide layer 103. A first parylene layer 105 is adjacent to the first metal oxide layer 103. A second metal oxide layer 103 is adjacent to the first parylene layer 105. A second parylene layer 105 may be deposited on the second metal oxide layer 103. The thin film stack 100 may also be referred to herein as a multilayer coating or film, or laminate/nano-laminate coating or film

An in situ surface treatment process for producing the thin film stack 100 is also described herein. The thin film stack 100 covers some or all of a substrate 101, with the substrate 101 disposed beneath the first metal oxide layer 103. Exemplary substrates 101 include components configured to be within an interior of an electronic device, such as a printed circuit board assembly (PCBA). The thin film stack 100 may provide enhanced properties, such as, for example, UV blocking, improved oxidation resistance, wear resistance, and water and corrosion resistance, to substrates.

In one embodiment, each parylene layer 105 is three hundred nanometers to one thousand nanometers thick and is comprised of either Parylene C or Parylene N. In other embodiments, the parylene layers 105 may be different thicknesses. For example, the parylene layers 105 may be as thin as one hundred nanometers, one hundred and fifty nanometers, or two hundred nanometers. In another example, the parylene layers 105 may be as thick as one thousand five hundred, two thousand, or two thousand five hundred nanometers for an embodiment in which mechanical forces between interconnecting structures are sufficient to puncture through the stack. In another example, the parylene layers 105 may be as thick as ten thousand nanometers, fifteen thousand nanometers, or twenty thousand nanometers for an embodiment in which mechanical forces between interconnecting structures are insufficient to puncture through the stack.

A variety of parylene materials may be used. As generally known in the art, parylene includes a variety of a number of unsubstituted and substituted poly(para-xylylene). Exemplary parylenes include parylene A (amino-modified parylene), parylene C (poly(chloro-p-xylylene)), parylene N (poly(p-xylylene)), parylene D (poly(dichloro-p-xylylene)), parylene F (which can specifically refer to parylene-VT4, parylene-AF4, or any other parylene with a fluorine atom or atoms in the molecular structure), as well as mixtures and derivatives thereof.

The thin film stack 100 may be applied in multiple layers. For example, the thin film stack may include a series of metal oxide layers 103 and parylene layers 105 in an alternating arrangement. In one embodiment, the thin film stack 100 may include a first metal oxide layer 103 applied to a substrate 101, and that first metal oxide layer 103 is also covered by a first parylene layer 105, with a second metal oxide layer 103 covering the first parylene layer 105 and repeated as many times as desired. In this exemplary arrangement, the coating system has four dyads including eight layers.

The specific technical aspects of functionality of each layer, and overall thin film design philosophy are described below.

The metal oxide layer is a thin, dense material which provides a barrier against diffusion of corrosive chemical species such as water, anions and cations in water, hydrocarbons, and gaseous species such as sulfur dioxide (SO₂).

Atomic layer deposition (ALD) is used to deposit aluminum oxide (Al₂O₃), titanium dioxide (TiO₂), silicon dioxide (SiO₂), and/or zirconium oxide (ZrO₂), or another similar or equivalent metal oxide over a substrate. ALD can be performed over a broad range of temperatures (25° C. to over 300° C.). ALD provides the capability to precisely control film thickness and uniformity and to combine thin layers (even down to sub-Angstrom thicknesses) to form metal oxide alloys and nanolaminate structures. More specifically, in some embodiments, ALD metal oxide nanolaminate layers of Al₂O₃, and TiO₂, or Al₂O₃ and SiO₂, can be deposited onto rigid or flexible substrates at temperatures as low as 60° C. using thermal or plasma-enhanced ALD process chemistries.

In some embodiments, a ten to thirty nanometer thick ALD layer deposited at 60-100° C. is sufficient to provide a good molecular diffusion barrier; in the case of water, a good diffusion barrier would allow water transport of less than 10⁻³ grams of H₂O per square meter of barrier area per day. Generally, diffusion barrier properties of a specific ALD metal oxide alloy or nanolaminate improve with increasing total layer thickness and degrade with decreasing ALD deposition process temperature. Barrier properties improve with total layer thickness up to a practical limit typical between thirty and fifty nanometer thick, at which point the diffusion inhibition performance is limited by intrinsic defects in the film and/or further improvement in diffusion inhibition becomes difficult to measure.

The ALD layer's resilience to fracture under tensile and compressive strain is inversely proportional to the film thickness; thinner films are, in general, more resilient to fracture. Using nanolaminate structures can increase fracture resilience by inhibiting propagation of defects and strain-induced nano-fractures through the film in the direction normal to the basal plane.

Therefore, embodiments of the specific metal oxide layer in this disclosure are designed to provide a balance between diffusion barrier properties and fracture resilience, thereby providing efficacy for applications involving flexible substrates and/or substrates which have a significant coefficient of thermal expansion mismatch.

The parylene layer is a polymer layer comprised of parylene-C, parylene-N, or other parylene materials and is deposited near ambient temperature. The parylene layer provides: (1) a diffusion barrier against corrosive species, (2) encapsulation of macroscopic particles on the substrate, (3) metal oxide defect ‘buffering’ and strain relaxation, (4) mechanical and chemical protection for the ALD metal oxides layers.

Diffusion Barrier—The parylene film provides a moderate level of diffusion inhibition, approximately in the range of 1-100 grams of H₂O per square meter of barrier area per day. Although much less effective than the ALD metal oxide layer, this added diffusion protection is important to the overall functionality of the multilayer film.

Particle and Substrate Defect Encapsulation—The overall performance of composite multilayer films incorporating ALD layers is typically limited by defects which are often caused by imperfections in the substrate and/or macroscopic foreign object debris on the substrate. 10-30 nm ALD metal oxide films have problems fully encapsulating and ‘locking’ particles and foreign object debris in place on the substrate. The parylene layer, due in part to the greater layer thickness and subsequently higher mechanical strength, can fix particles in place, encapsulate the particles, and smooth over ‘sharp features’ around particles and substrate defects.

Defect Buffering and Strain Relaxation-Localized defects are formed in the metal oxide film during the ALD process. Once a defect nucleates, the defect may propagate through the entire ALD layer. The parylene layer provides a buffering effect between defects in one ALD layer and the ALD layer above and below it; the parylene layer significantly reduces the likelihood of an ALD layer defect propagating to adjacent ALD layers. The parylene layer, being a softer material relative to the ALD metal oxide layer, also provides some degree of strain relaxation; the tensile/compressive strain in one ALD layer is not directly transferred to adjacent ALD layers, thus reducing strain effects in the ALD layers.

Metal Oxide Layer Protection—The metal oxide layers may be susceptible to degradation by mechanical abrasion and/or dissolution when submerged in liquids for a long period of time. The parylene layer (topmost layer in particular) provides a mechanical barrier over the metal oxide layers to protect the metal oxide layers from abrasion and direct contact with liquids.

The overall functionality of a multi-period metal-oxide/parylene superlattice is described as:

The base ALD layers provides a conformal diffusion inhibiting layer and promotes adhesion of parylene;

The intermediate ALD layers provide additional strong-diffusion inhibiting layers;

Intermediate layers of parylene provide some diffusion resilience, encapsulate substrate and particle defects, and limit transfer of strain and propagation of structural defects between ALD layers during compression/tension;

The top-most parylene layer provides diffusion resistance but is primarily to protect the underlying ALD layer from dissolution and damage from abrasion.

For some applications, four periods (dyads) of the ALD metal oxide/parylene superlattice film provide a good balance between economy and performance. Fewer periods can be used to improve economy at the cost of performance, or more periods can be used to improve overall film performance at increased expense.

In other embodiments, the order of the layers may be reversed so that the layer applied to the substrate is a parylene layer, and each period or dyad includes an ALD layer on top of a parylene layer. In further embodiments, some or all of the sequential layers of each material have a consistent thickness. Alternatively, the thickness of each sequential layer may vary from layer to layer.

Embodiments of the thin film stack 100 may have enhanced properties relative to the parylene layer 105 by itself. For example, transmission of water and other molecules through the thin film stack may be reduced by metal oxide covering the surface of a parylene layer 105 and depositing into defects, voids, and/or imperfections in the surface of a parylene only coating. Titanium oxide and zinc oxide or other metal oxides may provide enhanced UV protection to a parylene layer 105. Additionally, a metal oxide layer may inhibit degradation of parylene in high temperature oxidative environments (for example, hot air) by providing a diffusion barrier above a parylene layer.

As mentioned above, the thin film stack 100 may cover a substrate, with the substrate 101 disposed beneath and in contact with the first metal oxide layer 103. Exemplary substrates 101 may include components configured to be within an interior of an electronic device, such as within the interior of housing for the device. For example, the substrate 101 may be a printed circuit board assembly or PCBA. In other embodiments, the thin film stack 100 may cover at least some components that are exposed to the outside of the electronic device. Exemplary substrates 101 may also include a component of a mobile electronic device, an energy storage device such as a battery, an industrial device, a vehicular device, a precision mechanical device, a medical device, a scientific instrument, an article of clothing or the like. A substrate 101 that has been coated with the thin film stack 100 described herein may be referred to as a coated article. Although shown as layers, in some embodiments, the thin film stack 100 may fully or partially encapsulate the substrate 101.

Methods for applying the thin film stack 100 to a substrate 101 to produce a coated article are described. The layers of the thin film stack 100 may be applied in a single process or in two or more processes wherein different materials are applied to a substrate 101.

Referring to FIG. 3, a schematic diagram of a process 200 for forming a multi-layer thin film stack on a substrate is shown. The process 200 includes depositing 202 a first ALD layer of a first metal oxide to a substrate surface of a substrate. The process 200 includes depositing 204 a first parylene layer onto a surface of the first ALD layer to cover the first ALD layer. The process 200 further includes depositing 206 a second ALD layer of a second metal oxide onto a surface of the first parylene layer. The process 200 further includes depositing 208 a second parylene layer onto a surface of the second ALD layer to cover the second ALD layer. The depicted process 200 then ends.

In some embodiments, the discrete processes may be carried out by the same equipment, even in the same application zone (e.g., deposition chamber, etc.), or by separate pieces of equipment (e.g., a chemical vapor deposition (CVD) chamber for parylene and an atomic layer deposition (ALD) chamber for the metal oxide).

In an embodiment, a metal oxide layer 103 is deposited on a substrate 101 by chemical vapor deposition. The chemical vapor deposition process includes three major steps: vaporization, pyrolysis, and polymerization. The parameters of each stage can be determined for each material or combination of materials. For example, the vaporizer may operate in a temperature range of 120-170° C., the pyrolysis furnace may operate at a temperature range of about and inclusive of 550-650° C., and the deposition chamber may operate at a temperature range of about and inclusive of 20-150° C.

In an embodiment of a parylene-C deposition process, the vaporizer temperature is controlled between 150° C. to 165° C. to produce a consistent vapor pressure of dimer in the range of 600-800 mTorr, as measured by pressure sensor in the vaporizer section of deposition tool. Dimer vapor flows through the pyrolysis sub-system, which is operated between 580° C. and 610° C., where dimer is thermally cracked into monomer; the precise operating temperature of the pyrolysis sub-system is set dynamically based upon the molecular flow rate of dimer into the pyrolysis sub-system. The molecular flow rate is determined empirically from the absolute pressure of dimer in the vaporizer and the pressure of monomer in the deposition system. Monomer flows from the pyrolysis sub-system into the deposition chamber where parylene is deposited onto all exposed surfaces via an initial nucleation step followed by chain polymerization. The initial surface temperature of electronic parts and chamber surfaces is near ambient temperature at the beginning of the deposition process and slowly increases during the deposition process due to exothermic nature of parylene chain polymerization.

In some embodiments, the process 200 may also include the application of a mask to selected regions of the substrate to prevent at least one portion of the coating from being applied to those portions. In embodiments where discrete processes are used to form different portions of a coating, the mask may be present while at least one portion of the coating is applied to the substrate, but absent while at least one other portion of the coating is applied to the substrate; thus, some (masked) portions of the substrate will be covered by fewer portions of a coating than other (unmasked) portions of the substrate. In other embodiments, a mask may remain in place as all portions of a coating are applied to the substrate. As a result, the corrosion resistant coating will not cover those areas of the substrate.

Although the foregoing disclosure provides many specifics, these should not be construed as limiting the scope of any of the ensuing claims. Other embodiments may be devised which do not depart from the scopes of the claims. Features from different embodiments may be employed in combination. The scope of each claim is, therefore, indicated and limited only by its plain language and the full scope of available legal equivalents to its elements.

Reference throughout this specification to features, advantages, or similar language does not imply that all of the features and advantages that may be realized with the subject matter of the present disclosure should be or are in any single embodiment. Rather, language referring to the features and advantages is understood to mean that a specific feature, advantage, or characteristic described in connection with an embodiment is included in at least one embodiment of the present disclosure. Thus, discussion of the features and advantages, and similar language, throughout this specification may, but do not necessarily, refer to the same embodiment.

In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The present subject matter may be embodied in other specific forms without departing from its spirit or essential characteristics. The described embodiments are to be considered in all respects only as illustrative and not restrictive.

1. A multi-layer thin film stack comprising:
a first ALD layer of a first metal oxide deposited on a substrate surface of a substrate;
a first parylene layer covering the first ALD layer;
a second ALD layer of a second metal oxide covering the first parylene layer; and
a second parylene layer covering the second ALD layer.

2. The multi-layer thin film stack of claim 1, wherein the first ALD layer is comprised of an alloy of two or more following metal oxide materials: aluminum oxide (Al₂O₃), titanium dioxide (TiO₂), silicon dioxide (SiO₂), and zirconium oxide (ZrO₂).

3. The multi-layer thin film stack of claim 2, wherein the second ALD layer is comprised of an alloy of two or more following metal oxide materials: aluminum oxide (Al₂O₃), titanium dioxide (TiO₂), silicon dioxide (SiO₂), and zirconium oxide (ZrO₂).

4. The multi-layer thin film stack of claim 3, wherein the first and second ALD layer are comprised of a same alloy.

5. The multi-layer thin film stack of claim 5, wherein the first and second ALD layer are comprised of a different alloy.

6. The multi-layer thin film stack of claim 1, wherein the first and second parylene layers are at least one of parylene A, parylene C, parylene N, parylene D, parylene VT-4, parylene AF-4, or mixtures or derivations of parylene A, parylene C, parylene N, parylene D, parylene VT-4, parylene AF-4.

7. The multi-layer thin film stack of claim 1, wherein the first parylene layer and the second parylene layer are a same parylene material.

8. The multi-layer thin film stack of claim 1, wherein the first parylene layer and the second parylene layer are a different parylene material.

9. The multi-layer thin film stack of claim 1, wherein the first and second ALD layers each have a thickness between 10 and 30 nm.

10. The multi-layer thin film stack of claim 1, wherein the first and second ALD layers each have a thickness between 5 and 50 nm.

11. The multi-layer thin film stack of claim 1, wherein the first parylene layer has a thickness between 300 nm and 1000 nm.

12. The multi-layer thin film stack of claim 1, further comprising:
a third ALD layer of a third metal oxide covering the second parylene layer; and
a third parylene layer covering the third ALD layer.

13. The multi-layer thin film stack of claim 12, further comprising:
a fourth ALD layer of a fourth metal oxide covering the third parylene layer; and
a fourth parylene layer covering the fourth ALD layer.

14. A coated article comprising:
a substrate comprising a substrate surface; and
a thin film stack comprising:
a first ALD layer of a first metal oxide deposited on a substrate surface of a substrate;
a first parylene layer covering the first ALD layer;
a second ALD layer of a second metal oxide covering the first parylene layer; and
a second parylene layer covering the second ALD layer.

15. (canceled)

16. The coated corrosive sensitive article of claim 14, wherein the first ALD layer is comprised of an alloy of two or more following metal oxide materials: aluminum oxide (Al₂O₃), titanium dioxide (TiO₂), silicon dioxide (SiO₂), and zirconium oxide (ZrO₂).

17. A process for forming a multi-layer thin film stack on a substrate, comprising:
depositing a first ALD layer of a first metal oxide to a substrate surface of a substrate;
depositing a first parylene layer onto a surface of the first ALD layer to cover the first ALD layer; and
depositing a second ALD layer of a second metal oxide onto a surface of the first parylene layer; and
depositing a second parylene layer onto a surface of the second ALD layer to cover the second ALD layer.

18. The process of claim 17, wherein the first and second parylene layers are at least one of parylene A, parylene C, parylene N, parylene D, parylene VT-4, parylene AF-4, or mixtures or derivations of parylene A, parylene C, parylene N, parylene D, parylene VT-4, parylene AF-4.

19. The process of claim 18, wherein the first ALD layer is comprised of an alloy of two or more following metal oxide materials: aluminum oxide (Al₂O₃), titanium dioxide (TiO₂), silicon dioxide (SiO₂), and zirconium oxide (ZrO₂).

20. The process of claim 17, further comprising:
depositing a third ALD layer of a third metal oxide onto a surface of the second parylene layer; and
depositing a third parylene layer onto a surface of the third ALD layer to cover the third ALD layer.

21. The process of claim 17, wherein the second ALD layer is deposited at a temperature between 60-100° C.
